(19) United States
(12) Patent Application Publication
(10) Pub. No.: US 2009/0238007 A1
(43) Pub. Date: Sep. 24, 2009

(54) METHOD OF SUPPLYING AN OPERATING VOLTAGE OF A FLASH MEMORY DEVICE

(75) Inventor: Chae Kyu JANG, Icheon-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 12/117,700

(22) Filed: May 8, 2008

(30) Foreign Application Priority Data
Mar. 19, 2008 (KR) 10-2008-25459

(51) Int. Cl. G11C 11/34

(52) U.S. Cl. 365/185.19

(57) ABSTRACT

A method of supplying an operating voltage of a flash memory device includes supplying an operating voltage to a word line selected according to an input address, and changing a pass voltage according to a change of the operating voltage level. The pass voltage is supplied to unselected word lines other than the selected word line.

### CROSS-REFERENCES TO RELATED APPLICATIONS

The present application claims priority to Korean patent application number 10-2008-25459, filed on Mar. 19, 2008, which is incorporated by reference in its entirety.

### BACKGROUND OF THE INVENTION

The present invention relates to a method of supplying an operating voltage of a flash memory device and, more particularly, to a method of supplying an operating voltage of a flash memory device, which can control a pass voltage supplied to unselected word lines.

A well-known NAND flash memory device includes a memory cell array, a row decoder and a page buffer. The memory cell array includes a plurality of word lines extending along rows, a plurality of bit lines extending along columns, and a plurality of cell strings corresponding to the bit lines.

The row decoder connected to a string select line, word lines and a common source line is disposed on one side of the memory cell array, and the page buffer connected to the plurality of bit lines is disposed on the other side of the memory cell array.

In NAND flash memory devices, a reduction in the program speed and a cell threshold voltage distribution width becomes problematic. In a multi-level cell (MLC) having a MLC voltage distribution width, reducing the width of cell threshold voltage distributions is desirable.

A current program method employs an incremental step pulse programming (ISPP) method. In this method, a program operation is performed again on cells that do not pass a verify voltage level at a specific voltage level by increasing the voltage as high as a step voltage.

FIG. 1 shows conventional ISPP voltage levels for programming.

As shown in FIG. 1, when a program is performed using the ISPP method, a program start voltage V1 is applied to a selected word line as a program voltage. If the program does not pass program verification, the program voltage is increased as high as an ISPP voltage step Vs and the program is performed again.

A program is performed again on cells that have not been verified by increasing voltage as high as the voltage step Vs. If verification is not successful even after the program is performed up to the highest program voltage Vn set in a program process, the program fails.

Further, a pass voltage Vpass is applied to unselected word lines other than a word line on which the program is performed. The pass voltage Vpass functions to pass data such that memory cells connected to unselected word lines are turned on and, therefore, the data is programmed into memory cells connected to a selected word line.

Coupling is generated between cells that have not been programmed and cells that have been programmed resulting in disturbance. The disturbance phenomenon causes cells, which should not be programmed, to be programmed.

### BRIEF SUMMARY OF THE INVENTION

The present invention is directed towards a method of supplying an operating voltage of a flash memory device, which can provide a flexible pass voltage to an unselected word line in an operation of the flash memory device.

A method of supplying a program voltage of a flash memory device according to an aspect of the present invention includes supplying a program voltage of an ISPP method to a word line selected according to an input address. A pass voltage, which is supplied to unselected word lines other than the selected word line, is changed according to a change of the program voltage level. The changed pass voltage is then supplied.

The program voltage and the pass voltage are increased as high as a set voltage amount according to the ISPP method.

The pass voltage is changed to have the same voltage step as the changed program voltage.

A method of supplying a read voltage of a flash memory device according to another aspect of the present invention includes supplying a read voltage to a word line selected according to an input address. The read voltage is sequentially set. A pass voltage, which is supplied to unselected word lines other than the selected word line, is changed according to a change of the read voltage level. The changed pass voltage is then supplied.

When the read voltage is set to first to k^{th} read voltages in order of higher voltages, the pass voltage is set to first to k^{th} pass voltages in order of higher voltages.

A method of supplying an operating voltage of a flash memory device according to still another aspect of the present invention includes supplying an operating voltage to a word line selected according to an input address. A pass voltage, which is supplied to unselected word lines other than the selected word line, is changed according to a change of the operating voltage level. The changed pass voltage is then supplied.

When the flash memory device performs a program operation, a program voltage is applied to the selected word line, and the pass voltage, which is changed according to the same voltage step as a change of the program voltage, is applied to the unselected word lines.

The program voltage and the pass voltage are increased as high as a set voltage amount according to the ISPP method.

When the flash memory device performs a read operation, one of set read voltages is applied to the selected word line, and the pass voltage, which is set according to the read voltage level applied to the selected word line, is supplied to the unselected word lines.

When the read voltage is set to first to k^{th} read voltages in order of higher voltages, the pass voltage is set to first to k^{th} pass voltages in order of higher voltages.

### BRIEF DESCRIPTION OF THE DRAWINGS

FIG. 1 shows conventional ISPP voltage levels for programming;

FIG. 2A is a block diagram showing the construction of a NAND flash memory device;

FIG. 2B is a detailed circuit diagram of a memory cell array shown in FIG. 2A;

FIG. 2C shows program voltage levels provided to a selected word line for programming of FIG. 2A; and

FIG. 2D shows pass voltage levels provided to not-programmed word lines of FIG. 2A.

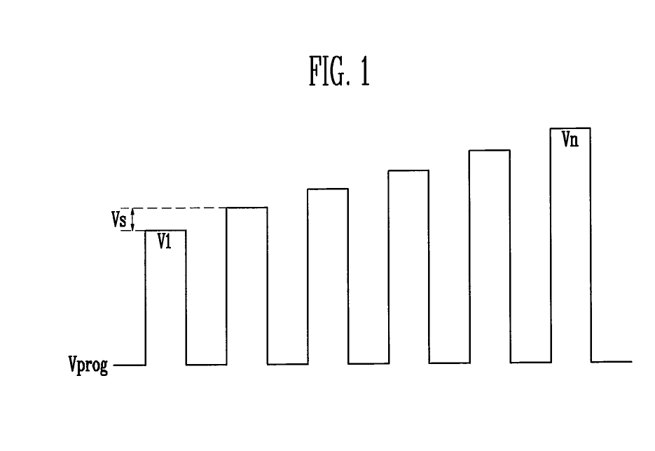

### DESCRIPTION OF SPECIFIC EMBODIMENTS

Specific embodiments according to the present invention will be described with reference to the accompanying drawings. However, the present invention is not limited to the disclosed embodiments, but may be implemented in various manners. The embodiments are provided to complete the disclosure of the present invention and to allow those having ordinary skill in the art to understand the scope of the present invention. The present invention is defined by the category of the claims.

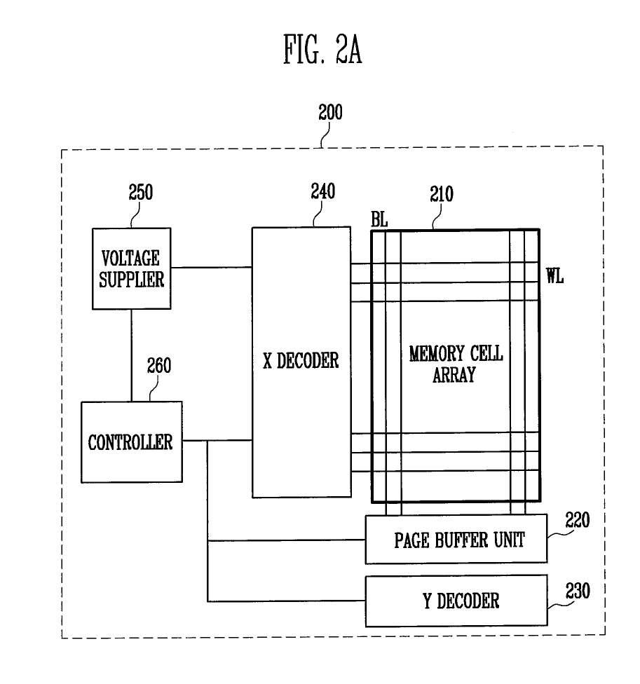

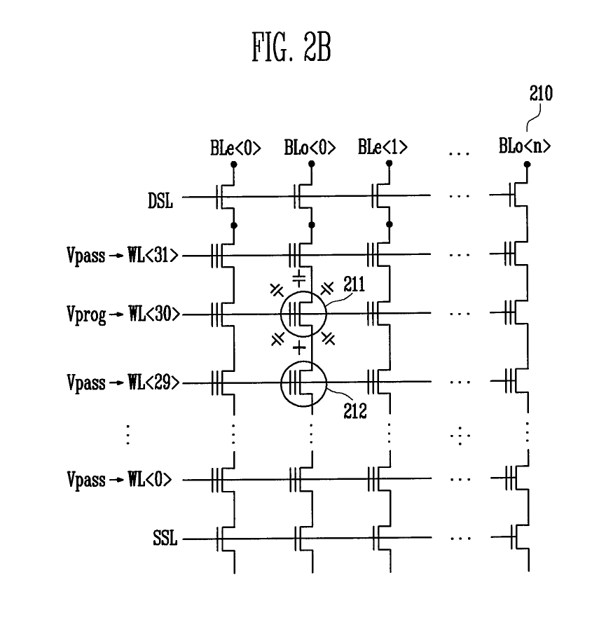

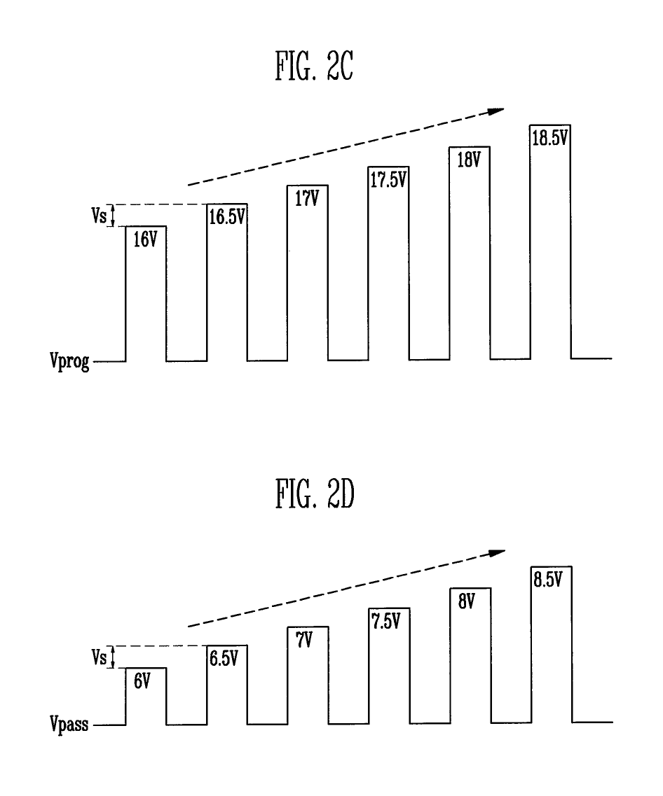

FIG. 2A is a block diagram showing the construction of a NAND flash memory device.

Referring to FIG. 2A, a NAND flash memory device 200 according to an embodiment of the present invention includes a memory cell array 210 in which a plurality of memory cells for data storage are constructed of word lines and bit lines, a page buffer unit 220 for programming data into the memory cell array 210 or reading data stored in the memory cell array 210, a Y decoder 230 for selecting the page buffer unit 220 according to an input address, an X decoder 240 for selecting the word lines of the memory cell array 210 according to an input address, a voltage supplier 250 for generating and providing operating voltages for the operation of the flash memory device 200, and a controller 260 for outputting a control signal to operate the flash memory device 200.

The memory cell array 210 includes the plurality of memory cells (not shown) that store data. The memory cells are arranged by the bit lines BL and the word lines WL.

The page buffer unit 220 includes a plurality of page buffer circuits. Each page buffer circuit is connected to a bit line pair of the memory cell array 210 and operates to program data into or read data from a memory cell to which the bit lines are connected.

The Y decoder 230 provides a data I/O path to the plurality of page buffer circuits of the page buffer unit 220 in response to the control signal. The X decoder 240 selects the word lines according to an input address.

The voltage supplier 250 generates and supplies voltages necessary for the operation of the flash memory device 200. The controller 260 outputs the control signal to control the operation of the flash memory device 200.

FIG. 2B is a detailed circuit diagram of the memory cell array shown in FIG. 2A.

Referring to FIG. 2B, the bit lines include even bit lines BLe and odd bit lines BLo, which are alternately arranged in a vertical direction. One bit line includes a plurality of memory cells C connected in series between a drain select transistor DST and a source select transistor SST.

The gates of the drain select transistors DST of the bit lines are commonly connected to a drain select line DSL. The gates of the source select transistors SST are commonly connected to a source line SSL.

The gates of the memory cells are commonly connected to first to thirty-second word lines WL<0> to WL<32> in a horizontal direction.

A cell for program into the memory cell array 210 can be selected by selecting the word line and the bit line. A program voltage Vprog is applied to a word line connected to a cell that will be programmed, and a pass voltage Vpass is applied to word lines connected to cells that will not be programmed.

The program voltage Vprog and the pass voltage Vpass are provided according to the ISPP method. That is, the program voltage Vprog and the pass voltage Vpass are increased and supplied as high as a set ISPP step voltage Vs whenever program does not pass at a start voltage.

The following drawing shows voltage levels supplied as the program voltage Vprog and the pass voltage Vpass.

FIG. 2C shows program voltage levels provided to a selected word line for programming of FIG. 2A. FIG. 2D shows pass voltage levels provided to not-programmed word lines of FIG. 2A.

In the program method according to an embodiment of the present invention, assuming that the program voltage Vprog and the pass voltage Vpass are set to the start voltages of 16V and 6V, respectively, and the ISPP step voltage Vs is 0.5V as shown in FIGS. 2C and 2D, voltages are supplied according to the ISPP method.

A program method, which is performed by applying the program voltage Vprog and the pass voltage Vpass as shown in FIGS. 2C and 2D, is described in more detail below with reference to FIG. 2B showing the memory cell array 210.

If it is sought to program the memory cell 211 of the thirty-first word line WL<30> in FIG. 2B, the memory cell 212 indicates one of the memory cells that will not be programmed.

For the purpose of program, 0V is applied to the bit line BLo<0> including the memory cell 211, and VCC is applied to the remaining bit lines BLe<0> and BLe<1> to BLo<n> and the drain select line DSL. The drain select transistors DST are turned off and the bit lines BLe<0> and BLe<1> to BLo<n> are floated. Accordingly, the power of a channel is set by the program voltage Vprog or the pass voltage Vpass supplied to the word line.

In general, in the program operation of a flash memory device, the pass voltage Vpass is fixed to 10V and applied. In this case, the voltage of a channel is about 8V due to the self-boosting effect and has a level change due to the high voltage. Thus, the threshold voltages of cells that should not be programmed can be changed.

Further, a pass disturbance phenomenon may be generated in a memory cell (for example, 212) due to a fixed pass voltage and the gap between levels of a channel. The memory cell 212 is included in the bit line BLo<0> including the memory cell 211 that will be programmed, but the memory cell 212 will not be programmed.

To prevent the pass disturbance problem, in the program operation according to an embodiment of the present invention, the program voltage Vprog and the pass voltage Vpass are supplied as follows.

The program voltage Vprog is applied to the thirty-first word line WL<30>, as shown in FIG. 2C. The pass voltage Vpass is applied to the first to thirtieth word lines WL<0> to WL<29> and the thirty-second word line WL<31>, as shown in FIG. 2D.

In the case where the program voltage Vprog and the pass voltage Vpass are supplied to the word lines, when the program voltage Vprog has a low voltage level, the pass voltage Vpass is also supplied as a low voltage level. Further, as the program voltage Vprog rises, the pass voltage Vpass also increases in the same manner.

If the program voltage Vprog and the pass voltage Vpass are applied as described above, pass disturbance and a self-boosting level can be controlled at a low level, thereby reducing the effects of disturbance and interference.

Disturbance occurring due to a read operation can also be reduced by increasing the pass voltage Vpass from a low voltage according to the level of a read voltage even when program is performed or data is read. The pass voltage Vpass is applied to word lines to which memory cells (for example, memory cell 212), which will not be read, are connected. However, at the read voltage, the pass voltage Vpass is not supplied according to the ISPP method, but a set read voltage level is changed in order to change the pass voltage Vpass. For example, in the case of a flash memory device including MLCs, two or more read voltages are set. Accordingly, a higher pass voltage Vpass is applied when a higher read voltage is used, and a lower pass voltage Vpass is applied when a lower read voltage is used.

The pass voltage Vpass can be controlled by control means, which is included in a flash memory device to control a voltage generator.

As described above, according to the method of supplying an operating voltage of a flash memory device in accordance with the present invention, of voltages supplied for a program or read operation of a flash memory device, a pass voltage applied to a word line comprised of memory cells on which the program or read operation will not be performed is changed according to a program or read voltage level. Accordingly, the effect of disturbance can be reduced.

The embodiments disclosed herein have been proposed to allow a person skilled in the art to easily implement the present invention, and the person skilled in the part may implement the present invention by a combination of these embodiments. Therefore, the scope of the present invention is not limited by or to the embodiments as described above, and should be construed to be defined only by the appended claims and their equivalents.

What is claimed is:

1. A method of supplying a program voltage of a flash memory device, the method comprising:
supplying a program voltage of an incremental step pulse programming (ISPP) method to a word line selected according to an input address;
changing a pass voltage according to a change of the program voltage level, wherein the pass voltage is supplied to unselected word lines other than the selected word line; and
supplying the changed pass voltage.

2. The method of claim 1, wherein the program voltage and the pass voltage are increased as high as a set voltage amount according to the ISPP method.

3. The method of claim 1, wherein the pass voltage is changed to have the same voltage step as the changed program voltage.

4. A method of supplying a read voltage of a flash memory device, the method comprising:
supplying a read voltage to a word line selected according to an input address, wherein the read voltage is sequentially set;
changing a pass voltage according to a change of the read voltage level, wherein the pass voltage is supplied to unselected word lines other than the selected word line; and
supplying the changed pass voltage.

5. The method of claim 4, wherein when the read voltage is set to first to k^{th} read voltages in order of higher voltages, the pass voltage is set to first to k^{th} pass voltages in order of higher voltages.

6. A method of supplying an operating voltage of a flash memory device, the method comprising:
supplying an operating voltage to a word line selected according to an input address;
changing a pass voltage according to a change of the operating voltage level, wherein the pass voltage is supplied to unselected word lines other than the selected word line; and
supplying the changed pass voltage.

7. The method of claim 6, further comprising:
when the flash memory device performs a program operation, applying a program voltage to the selected word line, and
applying the pass voltage to the unselected word lines, wherein the pass voltage is changed according to the same voltage step as a change of the program voltage.

8. The method of claim 7, wherein the program voltage and the pass voltage are increased as high as a set voltage amount according to an ISPP method.

9. The method of claim 6, further comprising:
when the flash memory device performs a read operation, applying one of set read voltages to the selected word line, and
supplying the pass voltage to the unselected word lines, wherein the pass voltage is set according to the read voltage level applied to the selected word line.

10. The method of claim 9, wherein when the read voltage is set to first to k^{th} read voltages in order of higher voltages, the pass voltage is set to first to k^{th} pass voltages in order of higher voltages.
